(19) United States
(12) Patent Application Publication
(10) Pub. No.: US 2008/0157832 A1
(43) Pub. Date: Jul. 3, 2008

(54) Power-On-Reset Circuit

(75) Inventors: Wonki PARK, Seoul (KR); Sungchul Lee, Gyeonggi-do (KR); Byeongho Choi, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: Korea Electronics Technology Institute, Sungnam-si (KR)

(21) Appl. No.: 11/685,799

(22) Filed: Mar. 14, 2007

(30) Foreign Application Priority Data
Dec. 28, 2006 (KR) 10-2006-0136304

(51) Int. Cl. H03K 17/14

(52) U.S. Cl. 327/143

(57) ABSTRACT

A power-on-reset circuit for generating a reset voltage including a voltage divider and a temperature compensator that is insensitive to a change in PVT (Process, Voltage, Temperature) is disclosed. The temperature compensator compensates for a voltage variation of the voltage divider in an inversely proportional direction of a voltage variation of the voltage divider. The power-on-reset circuit of the present invention generates a reset signal during a power-off as well as during a power-on.

### BACKGROUND OF THE INVENTION

1. Field of the Invention

The present invention relates to a power-on-reset circuit, and in particular to a power-on-reset circuit for generating a reset voltage including a voltage divider and a temperature compensator that is insensitive to a change in PVT (Process, Voltage, Temperature).

2. Description of Prior Art

A power-on-reset circuit refers to a circuit that initializes each node of a system by automatically generating a reset signal when a power is applied to a digital system.

FIG. 1 is a circuit diagram illustrating a conventional power-on-reset circuit.

Referring to FIG. 1, the conventional power-on-reset circuit comprises two inverters inv1 and inv2 and an RC circuit. A rise of a voltage of a node A lags behind a power supply voltage VDD after a delay of a RC time constant of the RC circuit. When the voltage of the node A is higher than a threshold voltage of the inverter inv1, the inverter inv1 operates such that an output of the power-on-reset circuit follows the power supply voltage VDD.

FIG. 2 is a graph illustrating an operational waveform of the conventional power-on-reset circuit of FIG. 1.

Referring to FIG. 2, the voltage of the node A rises after the delay of the RC time constant of the RC circuit, and the output of the power-on-reset circuit is delayed accordingly.

The conventional power-on-reset circuit of FIG. 1 is relatively simple and facile to embody and the reset signal is generated during a power-on. However, the voltage of the node A charged by the power supply voltage VDD falls after the delay of the RC time constant even when the power supply voltage VDD is reduced during a power-off. That is, when the power supply voltage VDD starts to fall, a discharge from the node A to the power supply occurs since the node A charged by the capacitor maintains a voltage higher than the power supply voltage VDD. Therefore, the voltage of the node A is not zero even when the power supply voltage VDD is zero, thereby not being capable of generating the reset signal when the power supply voltage VDD is removed. As a result, the conventional power-on-reset circuit cannot carry out a role of a reset circuit during the power-off.

Moreover, as shown in FIG. 2, the power-on-reset circuit of FIG. 1 values of R and C should be relatively large due to the RC delay of the node A during the power-on. Therefore, an area occupied the power-on-reset circuit of FIG. 1 is large when embodied as an integrated circuit.

FIG. 3 is a graph illustrating an operational waveform of the conventional power-on-reset circuit of FIG. 1 during the power-on and the power-off, wherein waveforms of VDD, node A, node B and output signal are shown.

As shown in FIG. 3, when VDD is applied, the voltage of the node A appears after the delay of the RC time constant. An output of the inverter inv1 at the node B which is also delayed. In addition, in accordance with the waveform of the output signal, while the power-on-reset circuit of FIG. 1 carries out a reset operation during the power-on, the power-on-reset circuit of FIG. 1 does not output the reset signal during the power-off.

FIG. 4 is a circuit diagram illustrating another conventional power-on-reset circuit.

Referring to FIG. 4, the conventional power-on-reset circuit employs MOS transistors instead of the resistor and the capacitor such that the conventional power-on-reset circuit occupies a small area.

Contrary to the power-on-reset circuit of FIG. 1, the conventional power-on-reset circuit of FIG. 4 carries out the reset operation during the power-off as well as during the power-on. The conventional power-on-reset circuit of FIG. 4 employs a PMOS transistor MP1 and a NMOS transistor MN1 wherein a voltage is divided using the PMOS transistor MP1 operating as a diode and the NMOS transistor operating as a resistor. Therefore, contrary to the power-on-reset circuit of FIG. 1 wherein the voltage of the node A rises to VDD after the delay of the RC time constant, the voltage of the node A is determined between the power supply voltage VDD and a ground GND as shown in FIG. 5 due to the voltage division of the diode and the resistor.

Moreover, since the conventional power-on-reset circuit of FIG. 4 does not include the capacitor, the voltage of the node A is determined by the PMOS transistor MP1 and the NMOS transistor MN1 during the power-off to carry out the reset operation.

However, the conventional power-on-reset circuit of FIG. 4 is extremely sensitive to a change in a temperature. For instance, a threshold voltage of the PMOS transistor MP1 decreases as the temperature rises. Therefore, a voltage of a node A is increased as shown in FIG. 1. When the voltage of the node A is increased, a moment at which the reset signal is outputted changes as shown in FIG. 6. Since the conventional power-on-reset circuit of FIG. 4 is sensitive to the change in the temperature, the conventional power-on-reset circuit of FIG. 4 cannot be applied to a circuit requiring an accurate reset signal.

### SUMMARY OF THE INVENTION

It is an object of the present invention to provide a power-on-reset circuit that generates a reset signal when a power is turned on and turned off using a voltage divider and a temperature compensator, occupies a small area since a capacitor is not used, and is insensitive to the PVT.

In order to achieve the above-described objects of the present invention, there is provided a power-on-reset circuit comprising: a voltage divider for dividing a power supply voltage; a temperature compensator for outputting a voltage inversely proportional to an output signal of the voltage divider; and a reset signal generator for generating a reset signal according to an output voltage of the temperature compensator.

Preferably, the voltage divider comprises a first PMOS transistor and a first NMOS transistor connected in series between a power supply for providing the power supply voltage and a ground wherein a gate of the first PMOS transistor is connected to a connection node of the first PMOS transistor and the first NMOS transistor to serve as an output terminal of the voltage divider and a gate of the first NMOS transistor is connected to the power supply.

Preferably, the temperature compensator comprises a second PMOS transistor and a second NMOS transistor connected in series between a power supply for providing the power supply voltage and a ground wherein a gate of the second PMOS transistor is connected to an output terminal of the power supply and a gate of the second NMOS transistor is connected to a connection node of the second PMOS transistor and the second NMOS transistor to serve as an output terminal of the temperature compensator.

Preferably, the temperature compensator comprises a second PMOS transistor and a second resistor connected in series between a power supply for providing the power supply voltage and a ground wherein a gate of the second PMOS transistor is connected to an output terminal of the power supply and a connection node of the second PMOS transistor and the second resistor serves as an output terminal of the temperature compensator.

The reset signal generator may comprise a first resistor and a third NMOS transistor connected in series between a power supply for providing a power supply voltage and a ground; a first inverter connected to a connection node of the first resistor and the third NMOS transistor for inverting a voltage of the connection node the first resistor and the third NMOS transistor; a second inverter for inverting an output of the first inverter; a third PMOS transistor connected between the power supply and a connection node of the first inverter and the second inverter, a gate of the third PMOS transistor being connected to an output terminal of the second inverter; and a third inverter for inverting an output of the second inverter, wherein the output signal of the temperature compensator is inputted to a gate of the third NMOS transistor.

There is also provided a method for generating a power-on-reset signal, the method comprising: generating an output voltage of a voltage divider, a voltage division ratio of the voltage divider varying according to a temperature; generating a voltage inversely proportional to a magnitude of the output voltage of the voltage divider to compensate for a variation according to the temperature; and outputting a reset signal according to the voltage inversely proportional to the magnitude of the output voltage of the voltage divider.

### BRIEF DESCRIPTION OF THE DRAWINGS

FIG. 1 is a circuit diagram illustrating a conventional power-on-reset circuit.

FIG. 2 is a graph illustrating an operational waveform of the conventional power-on-reset circuit of FIG. 1.

FIG. 3 is a graph illustrating an operational waveform of the conventional power-on-reset circuit of FIG. 1 during a power-off.

FIG. 4 is a circuit diagram illustrating another conventional power-on-reset circuit.

FIG. 5 is a graph illustrating an operational waveform of the conventional power-on-reset circuit of FIG. 4.

FIG. 6 is a graph illustrating an operational waveform of the conventional power-on-reset circuit of FIG. 4 according to a temperature.

FIG. 7 is a circuit diagram illustrating a power-on-reset circuit in accordance with a first embodiment of the present invention.

FIG. 8 is a graph illustrating an operational waveform of the power-on-reset circuit according to a temperature in accordance with a first embodiment of the present invention.

FIG. 9 is a circuit diagram illustrating a power-on-reset circuit in accordance with a second embodiment of the present invention.

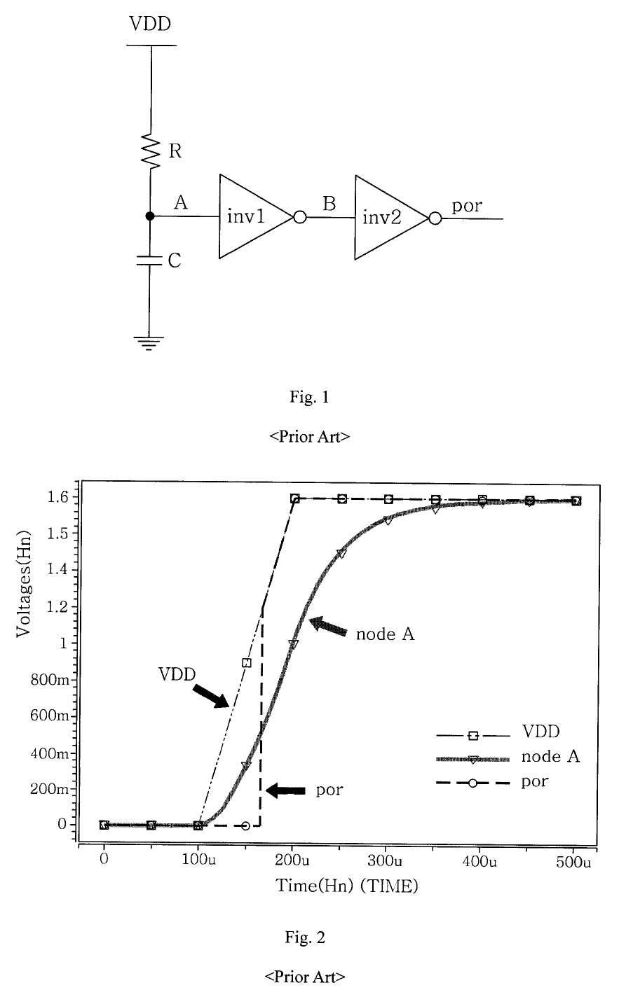

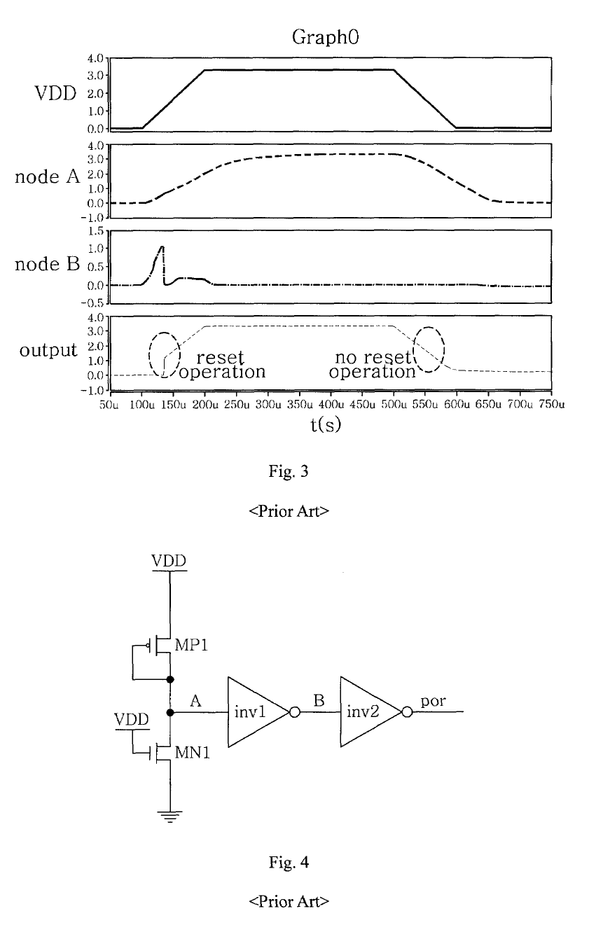

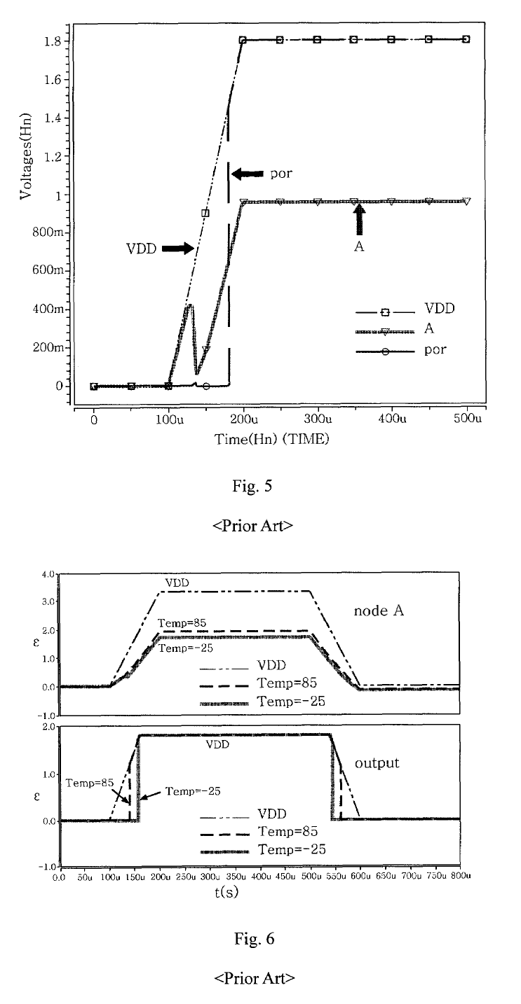

### DETAILED DESCRIPTION OF THE PREFERRED EMBODIMENTS

Preferred embodiments of the present invention will now be described in detail with reference to the accompanied drawings. The preferred embodiments of the present invention may vary in their forms, and a scope of the present invention should not be limited to the embodiments described below. The preferred embodiments of the present invention are provided so as to give a complete description of the present invention to a skilled in the art.

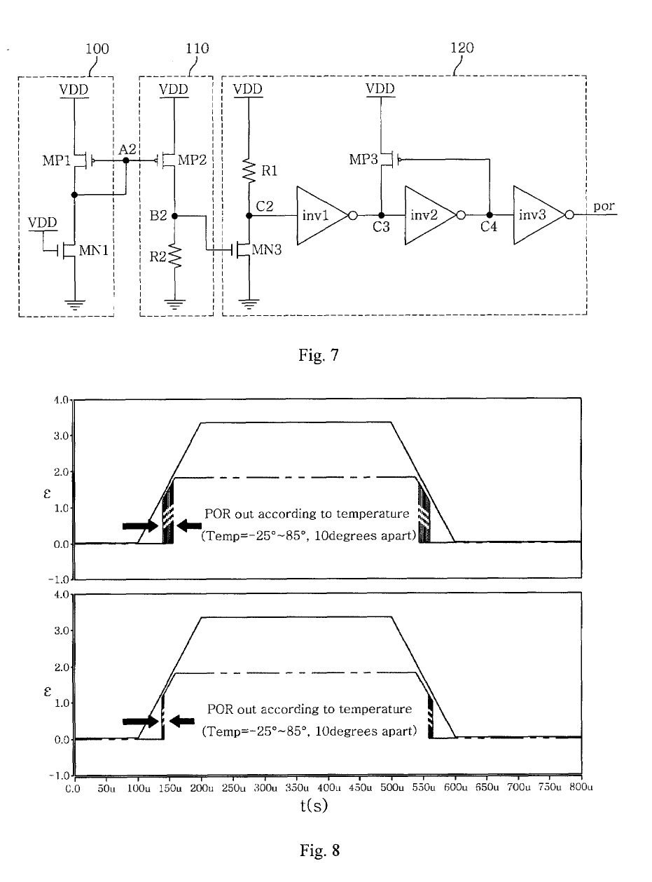

FIG. 7 is a circuit diagram illustrating a power-on-reset circuit in accordance with a first embodiment of the present invention.

Referring to FIG. 7, the power-on-reset circuit in accordance with the first embodiment of the present invention comprises a voltage divider 100, a temperature compensator 110 and a reset signal generator 120.

The voltage divider 100 outputs a voltage obtained by dividing a power supply voltage VDD by a predetermined ratio.

Preferably, the voltage divider 100 comprises a first PMOS transistor MP1 and a first NMOS transistor MN1 connected in series between a power supply (not shown) for providing the power supply voltage VDD and a ground or a substrate voltage VSS.

A gate of the first PMOS transistor MP1 is connected to a connection node A2 of the first PMOS transistor MP1 and the first NMOS transistor MN1. The gate of the first PMOS transistor MP1 serves as an output terminal of the voltage divider 100. In addition, a gate of the first NMOS transistor MN1 is connected to the power supply.

The temperature compensator 110 outputs a voltage inversely proportional to an output voltage of the voltage divider 100.

Preferably, the temperature compensator 110 comprises a second PMOS transistor MP2 and a second NMOS transistor MN2 connected in series between the power supply for providing the power supply voltage VDD and the ground or the substrate voltage VSS.

A gate of the second PMOS transistor MP2 is connected to the output terminal of the power supply, and a gate of the second NMOS transistor MN2 is connected to a connection node B2 of the second PMOS transistor MP2 and the second NMOS transistor MN2. The gate of the second NMOS transistor MN2 serves as an output terminal of the temperature compensator 110.

The reset signal generator 120 generates a reset signal according to an output voltage of the temperature compensator 110.

Preferably, the reset signal generator 120 comprises a first resistor R1, a third NMOS transistor MN3, a first inverter inv1, a second inverter inv2, a third PMOS transistor MP3 and a third inverter inv3.

The first resistor R1 and the third NMOS transistor MN3 are connected in series between the power supply for providing the power supply voltage VDD and the ground or the substrate voltage VSS. The output signal of the temperature compensator 110 is inputted to a gate of the third NMOS transistor MN3.

The first inverter inv1 is connected to a connection node C2 of the first resistor R1 and the third NMOS transistor MN3 to invert a voltage of the connection node the first resistor R1 and the third NMOS transistor MN3.

The second inverter inv2 inverts an output of the first inverter inv1.

The third PMOS transistor MP3 is connected between the power supply and a connection node C3 of the first inverter inv1 and the second inverter inv2, wherein a gate of the third PMOS transistor MP3 is connected to an output terminal of the second inverter inv2.

The third inverter inv3 inverts an output of the second inverter inv2.

An operation method of the power-on-reset circuit of FIG. 7 is as follows.

The voltage divider 100 divides the power supply voltage VDD according to a ratio of the first PMOS transistor MP1 and the first NMOS transistor MN1.

The voltage division ratio may be adjusted by varying a width and a length of the first PMOS transistor MP1 and the first NMOS transistor MN1. The voltage of the node A2 according to the division ratio of the voltage divider 100 increases proportional to a temperature. A variation of the output voltage of the voltage divider 100 is compensated by the temperature compensator 110. Specifically, the voltage of the node A2 which increases proportional to a temperature is converted to a current by the second PMOS transistor MP2. The current flowing through the second PMOS transistor MP2 decreases as the voltage of the node A2 increases and increases as the voltage of the node A2 decreases. That is, the increase in the voltage of the node A2 represents a decrease in |V_{gs}| value of the second PMOS transistor MP2. In other words, when the output voltage of the voltage divider 100 increases, the current of the second PMOS transistor MP2 is decreased, thereby decreasing a voltage of the node B2. When the output voltage of the voltage divider 100 decreases, the current of the second PMOS transistor MP2 is increased, thereby increasing a voltage of the node B2. Therefore, a voltage variation of the node A2 according to the temperature appears in an opposite direction (inversely proportional direction or compensating direction) of a voltage variation of the node B2 by the temperature compensator 110.

FIG. 8 is a graph illustrating an operational waveform of the power-on-reset circuit according to the temperature in accordance with the first embodiment of the present invention.

As shown in FIG. 8, effect of the temperature on the power-on-reset circuit in accordance with the present invention is small compared to the conventional circuit.

Table 1 illustrates a simulation result according to a PVT (Process, Voltage, Temperature) of the power-on-reset circuit in accordance with the present invention and the conventional circuit.

TABLE 1

| | | V135 | | | V24 | | |
|---|---|---|---|---|---|---|---|
| version | corner | MIN | MAX | Δ | MIN | MAX | Δ |
| Conventional | TT | 1.35 | 1.88 | 0.97 | 1.99 | 2.80 | 1.52 |
| | SS | 1.57 | 2.09 | | 2.32 | 3.12 | |
| | FF | 1.12 | 1.67 | | 1.60 | 2.44 | |
| Present invention | TT | 1.27 | 1.36 | 0.40 | 2.23 | 2.32 | 0.62 |
| | SS | 1.41 | 1.54 | | 2.47 | 2.61 | |
| | FF | 1.13 | 1.19 | | 1.99 | 2.03 | |

In table 1, ‘V135’ represents a case wherein the reset signal is generated when the power supply voltage VDD reaches 1.35V, and ‘V24’ represents a case wherein the reset signal is generated when the power supply voltage VDD reaches 2.4V. The variation of the PVT simulation result of the circuit in accordance with the present invention is reduced to less than one half of the conventional circuit even when the voltage at which the reset signal is generated is changed. While 90% of the variation according to the temperature is eliminated, 60% of an entire PVT variation is eliminated due to a PVT variation of a passive element such as the resistor. Therefore, the disadvantages of the conventional circuit are overcome by the circuit in accordance with the present invention.

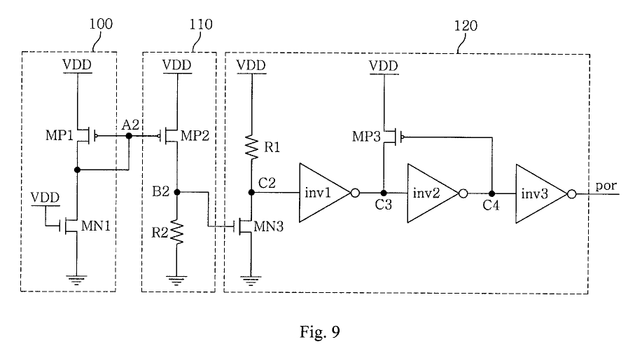

FIG. 9 is a circuit diagram illustrating a power-on-reset circuit in accordance with a second embodiment of the present invention.

Referring to FIG. 9, the power-on-reset circuit in accordance with the second embodiment of the present invention is identical to that of the first embodiment except the temperature compensator 110. Therefore, description will be focused on the temperature compensator 110.

The temperature compensator 110 of the power-on-reset circuit in accordance with the second embodiment of the present invention comprises a second PMOS transistor MP2 and a second resistor R2 connected in series between a power supply for providing a power supply voltage and a ground or a substrate voltage VSS. A gate of the second PMOS transistor MP2 is connected to an output terminal of the power supply, and a connection node B2 of the second PMOS transistor and the second resistor serves as an output terminal of the temperature compensator.

As described above, the power-on-reset circuit in accordance with the present invention may generate the reset signal when a power is turned on and turned off using the voltage divider and the temperature compensator, occupies a small area since a capacitor is not used, and is insensitive to the PVT.

1. A power-on-reset circuit comprising:
a voltage divider for dividing a power supply voltage;
a temperature compensator for outputting a voltage inversely proportional to an output signal of the voltage divider; and
a reset signal generator for generating a reset signal according to an output voltage of the temperature compensatory,
wherein the temperature compensator comprises a second PMOS transistor and a second NMOS transistor connected in series between a power supply for providing the power supply voltage and a ground, and
wherein a gate of the second PMOS transistor is connected to an output terminal of the voltage divider, and a gate of the second NMOS transistor is connected to a connection node of the second PMOS transistor and the second NMOS transistor to serve as an output terminal of the temperature compensator.

2. The circuit in accordance with claim 1, wherein the voltage divider comprises a first PMOS transistor and a first NMOS transistor connected in series between a power supply for providing the power supply voltage and a ground wherein a gate of the first PMOS transistor is connected to a connection node of the first PMOS transistor and the first NMOS transistor to serve as an output terminal of the voltage divider and a gate of the first NMOS transistor is connected to the power supply.

3. (canceled)

4. The circuit in accordance with claim 1, wherein the temperature compensator comprises a second PMOS transistor and a second resistor connected in series between a power supply for providing the power supply voltage and a ground wherein a gate of the second PMOS transistor is connected to an output terminal of the power supply and a connection node of the second PMOS transistor and the second resistor serves as an output terminal of the temperature compensator.

5. The circuit in accordance with claim 1, wherein the reset signal generator comprises:
a first resistor and a third NMOS transistor connected in series between a power supply for providing a power supply voltage and a ground;
a first inverter connected to a connection node of the first resistor and the third NMOS transistor for inverting a voltage of the connection node the first resistor and the third NMOS transistor;
a second inverter for inverting an output of the first inverter;
a third PMOS transistor connected between the power supply and a connection node of the first inverter and the second inverter, a gate of the third PMOS transistor being connected to an output terminal of the second inverter; and
a third inverter for inverting an output of the second inverter,
wherein the output signal of the temperature compensator is inputted to a gate of the third NMOS transistor.

6. A method for generating a power-on-reset signal, the method comprising:
generating an output voltage of a voltage divider, a voltage division ratio of the voltage divider varying according to a temperature;
generating a voltage inversely proportional to a magnitude of the output voltage of the voltage divider to compensate for a variation according to the temperature; and
outputting a reset signal according to the voltage inversely proportional to the magnitude of the output voltage of the voltage divider,
wherein the generating the voltage inversely proportional to a magnitude of the output voltage of the voltage divider is performed using a temperature compensator comprising a PMOS transistor and an NMOS transistor connected in series between a power supply for providing the power supply voltage and a ground, and
wherein a gate of the PMOS transistor is connected to an output terminal of the voltage divider, and a gate of the NMOS transistor is connected to a connection node of the PMOS transistor and the NMOS transistor to serve as an output terminal of the temperature compensator.
